(19) United States
(12) Patent Application Publication
(10) Pub. No.: US 2026/0269834 A1
(43) Pub. Date: Sep. 10, 2026

(54) Digital Phase-Locked Loop Circuitry

(71) Applicant: Apple Inc., Cupertino, CA (US)

(72) Inventors: Kazimierz Eugeniusz Szczypinski, Unterhaching (DE); Peter L Preyler, Weyer (AT); Herwig Dietl-Steinmaurer, Wels (AT); Christian Wicpalek, Oberneukirchen (AT); Thomas Mayer, Linz (AT)

(21) Appl. No.: 19/075,430

(22) Filed: Mar. 10, 2025

(51) Int. Cl. H03L 7/099; H03L 7/087; H03L 7/093

(52) U.S. Cl. CPC H03L 7/0992; H03L 7/087; H03L 7/093

(57) ABSTRACT

An electronic device may be provided with phase-locked loop (PLL) circuitry that includes a digitally controlled oscillator (DCO), frequency divider, time-to-digital converter (TDC), loop filter, and sigma delta modulator (SDM). The DCO may generate an output clock signal. The frequency divider may generate a feedback clock signal based on the output clock signal and a division ratio. The SDM may control the division ratio. The PLL circuitry may lock while the DCO remains free running. To lock the PLL circuitry, the TDC and loop filter may measure a phase error of the feedback clock signal and a channel word provided to the SDM may be modified based on the measured phase error. This may adjust a channel frequency of the SDM until the channel frequency aligns with the frequency of the output clock signal and a phase of the feedback clock signal aligns with a reference clock phase.

### FIELD

This disclosure relates generally to electronic devices, including electronic devices with communications circuitry.

### BACKGROUND

Electronic devices are often provided with communications capabilities. An electronic device with communications capabilities has communications circuitry that transmits and/or receives signals using a clock signal. The communications circuitry can include a phase-locked loop that outputs the clock signal. It can be challenging to design a satisfactory phase-locked loop for communications circuitry in an electronic device.

### SUMMARY

An electronic device may be provided with communications circuitry. The communications circuitry may include phase-locked loop (PLL) circuitry. The PLL circuitry may include a digitally controlled oscillator (DCO), a frequency divider, a time-to-digital converter (TDC), a loop filter, and a sigma delta modulator (SDM). The TDC may be communicatively coupled between the frequency divider and the loop filter. The loop filter may be communicatively coupled between the TDC and the SDM.

The DCO may generate an output clock signal. The frequency divider may generate a feedback clock signal based on the output clock signal and a division ratio. The SDM may control the division ratio of the frequency divider. The PLL circuitry may lock the output clock signal while the DCO remains in a free running state at a constant setting. To lock the PLL circuitry after a loop of the PLL circuitry has closed, the TDC and loop filter may measure a phase error of the feedback clock signal (e.g., a phase error between the feedback clock signal and a reference clock signal), and a channel word supplied to the SDM may be modified based on the measured phase error. This may effectively adjust a channel frequency of the SDM until the channel frequency aligns with the frequency of the output clock signal and a phase of the feedback clock signal aligns with a phase of the reference clock signal. This may serve to rapidly lock the PLL circuitry and may allow for long time period measurements of the DCO to be performed while the DCO remains in a free-running state.

An aspect of the disclosure provides phase-locked loop (PLL) circuitry. The PLL circuitry can include a time-to-digital converter (TDC), wherein a first input of the TDC is configured to receive a reference clock signal. The PLL circuitry can include a frequency divider, wherein an output of the frequency divider is communicatively coupled to a second input of the TDC. The PLL circuitry can include a sigma delta modulator (SDM), wherein a first output of the SDM is communicatively coupled to a first input of the frequency divider. The PLL circuitry can include a loop filter communicatively coupled between an output of the TDC and an input of the SDM.

An aspect of the disclosure provides a method of operating phase-locked loop (PLL) circuitry. The method can include generating, using a digitally controlled oscillator (DCO), an output clock signal. The method can include generating, using a frequency divider, a feedback clock signal based on the output clock signal and a division ratio. The method can include locking the PLL circuitry by adjusting, using a sigma delta modulator (SDM), the division ratio according to a channel word that has been corrected based on a phase error of the feedback clock signal, wherein the DCO generates the output clock signal based on a digital control signal that remains at a constant value while the PLL circuitry locks.

An aspect of the disclosure provides circuitry. The circuitry can include a digitally controlled oscillator (DCO) configured to generate an output clock signal. The circuitry can include a frequency divider configured to generate a feedback clock signal based on the output clock signal and a division ratio. The circuitry can include a sigma delta modulator (SDM) communicatively coupled to an input of the frequency divider. The circuitry can include a loop filter communicatively coupled between an output of the frequency divider and an input of the SDM. The loop filter can be configured to generate a filtered phase error signal based on the feedback clock signal and a reference clock signal. The SDM can be configured to adjust the division ratio of the frequency divider based on the filtered phase error signal.

### BRIEF DESCRIPTION OF THE DRAWINGS

FIG. 1 is a diagram of an illustrative electronic device having wireless circuitry in accordance with some embodiments.

FIG. 2 is a diagram of illustrative wireless circuitry having a transceiver in accordance with some embodiments.

FIG. 3 is a diagram of illustrative wireless circuitry having a mixer that receives a local oscillator signal from phase-locked loop (PLL) circuitry in accordance with some embodiments.

FIG. 4 is a circuit diagram of illustrative PLL circuitry including a digitally controlled oscillator (DCO) that is locked via adjustment to a channel word supplied to a sigma delta modulator in accordance with some embodiments.

FIG. 5 is a flow chart of illustrative operations involved in operating PLL circuitry of the type shown in FIG. 4 in accordance with some embodiments.

FIG. 6 is a timing diagram showing how illustrative PLL circuitry of the type shown in FIG. 4 may become locked in accordance with some embodiments.

FIG. 7 is a timing diagram showing how illustrative PLL circuitry of the type shown in FIG. 4 may lock to different frequencies of a DCO in accordance with some embodiments.

### DETAILED DESCRIPTION

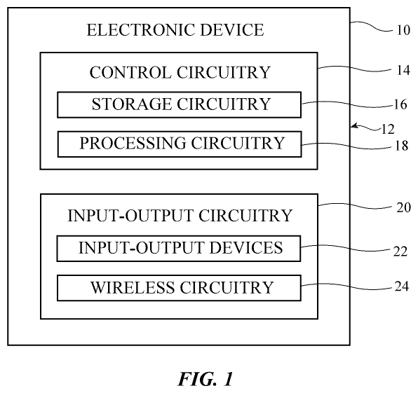

FIG. 1 is a block diagram of an electronic device 10 that may be provided with communications circuitry. The communications circuitry transmits and/or receives signals using one or more clock signals generated by one or more phase-locked loops (PLLs). Device 10 may be a computing device such as a laptop computer, a desktop computer, a computer monitor containing an embedded computer, a tablet computer, a cellular telephone, a media player, or another handheld or portable electronic device, a smaller device such as a wristwatch device, a pendant device, a headphone or earpiece device, a device embedded in eyeglasses, goggles, a helmet, or other equipment worn on a user's head (e.g., an augmented, virtual, or mixed reality head-mounted display device), or another wearable or miniature device, a television, a computer display (e.g., that does not contain an embedded computer), a gaming device, a navigation device, an embedded system such as a system in which electronic equipment with a display is mounted in a kiosk or automobile, a wireless internet-connected voice-controlled speaker, a home entertainment device, a remote control device, a gaming controller, a peripheral user input device, a wireless base station or access point, equipment that implements the functionality of two or more of these devices, or other electronic equipment.

As shown in the functional block diagram of FIG. 1, device 10 may include components located on or within an electronic device housing such as housing 12. Housing 12, which may sometimes be referred to as a case, may be formed from plastic, glass, ceramics, fiber composites, metal (e.g., stainless steel, aluminum, metal alloys, etc.), other suitable materials, or a combination of these materials. In some embodiments, some or all of housing 12 may be formed from dielectric or other low-conductivity material (e.g., glass, ceramic, plastic, sapphire, etc.). In other embodiments, housing 12 or at least some of the structures that make up housing 12 may be formed from metal elements.

Device 10 may include control circuitry 14. Control circuitry 14 may include storage such as storage circuitry 16. Storage circuitry 16 may include hard disk drive storage, nonvolatile memory (e.g., flash memory or other electrically-programmable-read-only memory configured to form a solid-state drive), volatile memory (e.g., static or dynamic random-access-memory), etc. Storage circuitry 16 may include storage that is integrated within device 10 and/or removable storage media.

Control circuitry 14 may include processing circuitry such as processing circuitry 18. Processing circuitry 18 may be used to control the operation of device 10. Processing circuitry 18 may include on one or more processors such as microprocessors, microcontrollers, digital signal processors, host processors, baseband processor integrated circuits, application specific integrated circuits, central processing units (CPUs), application processors, graphics processing units (GPUs), etc. Control circuitry 14 may be configured to perform operations in device 10 using hardware (e.g., dedicated hardware or circuitry), firmware, and/or software. Software code for performing operations in device 10 may be stored on storage circuitry 16 (e.g., storage circuitry 16 may include non-transitory (tangible) computer readable storage media that stores the software code). The software code may sometimes be referred to as program instructions, software, data, instructions, or code. Software code stored on storage circuitry 16 may be executed by processing circuitry 18.

Control circuitry 14 may be used to run software on device 10 such as satellite navigation applications, internet browsing applications, voice-over-internet-protocol (VOIP) telephone call applications, email applications, media playback applications, operating system functions, etc. To support interactions with external equipment, control circuitry 14 may be used in implementing wireless communications protocols (sometimes also referred to as communications protocols or communications standards). Communications protocols (standards) that may be implemented using control circuitry 14 include wireless local area network (WLAN) protocols (e.g., IEEE 802.11 protocols-sometimes referred to as Wi-Fi® such as a Wi-Fi 6 protocol, a Wi-Fi 7 protocol, or other Wi-Fi protocols), protocols for other short-range wireless communications links such as the Bluetooth® protocol or other wireless personal area network (WPAN) protocols, IEEE 802.11ad protocols (e.g., ultra-wideband protocols), cellular telephone protocols (e.g., 3G protocols, 4G (LTE) protocols, 3GPP Fifth Generation (5G) New Radio (NR) protocols, Sixth Generation (6G) protocols, sub-THz protocols, THz protocols, etc.), satellite navigation system protocols (e.g., global positioning system (GPS) protocols, global navigation satellite system (GLONASS) protocols, etc.), satellite communications (satcom) protocols, antenna-based spatial ranging protocols, optical communications protocols, or any other desired communications protocols. Each communications protocol may be associated with a corresponding radio access technology (RAT) that specifies the physical connection methodology used in implementing the protocol (e.g., used in transmitting and/or receiving radio-frequency signals under or according to the protocol).

Device 10 may include input-output circuitry 20. Input-output circuitry 20 may include input-output devices 22. Input-output devices 22 may be used to allow data to be supplied to device 10 and to allow data to be provided from device 10 to external devices. Input-output devices 22 may include user interface devices, data port devices, and other input-output components. For example, input-output devices 22 may include touch sensors, displays (e.g., touch-sensitive and/or force-sensitive displays), light-emitting components such as displays without touch sensor capabilities, buttons (mechanical, capacitive, optical, etc.), scrolling wheels, touch pads, key pads, keyboards, microphones, cameras, buttons, speakers, status indicators, audio jacks and other audio port components, digital data port devices, motion sensors (accelerometers, gyroscopes, and/or compasses that detect motion), capacitance sensors, proximity sensors, magnetic sensors, force sensors (e.g., force sensors coupled to a display to detect pressure applied to the display), etc. In some configurations, keyboards, headphones, displays, pointing devices such as trackpads, mice, and joysticks, and other input-output devices may be coupled to device 10 using wired or wireless connections (e.g., some of input-output devices 22 may be peripherals that are coupled to a main processing unit or other portion of device 10 via a wired or wireless link).

Input-output circuitry 20 may include communications circuitry that supports communications between components of device 10 and/or between device 10 and one or more external devices. The communications circuitry may include wired communications circuitry that conveys signals via one or more wired communications links over one or more wired paths (e.g., optical fiber paths, Ethernet paths, coaxial cable paths, conductive lines, serial paths, digital paths, analog paths, data paths, signal paths, interconnects, ports, etc.). Additionally, or alternatively, the communications circuitry may include wireless circuitry 24 that supports wireless communications (e.g., communications using wireless radio-frequency signals). Wireless circuitry 24 (sometimes referred to herein as wireless communications circuitry 24) may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s).

Wireless communications performed by wireless circuitry 24 may include or involve wireless data communications (e.g., where wireless data is carried by radio-frequency signals conveyed between wireless circuitry 24 and other communications equipment bidirectionally or unidirectionally), radio-frequency signal transmission, radio-frequency signal reception, and/or radio-based spatial ranging/sensing (e.g., radio detection and ranging (radar) operations, shorter range object detection such as near-field radio-frequency signal-based object detection, etc.). Radio-frequency signals conveyed by wireless circuitry 24 may include or carry wireless data (e.g., organized into frames, packets, symbols, datagrams, etc.), radar or other spatial ranging waveforms, continuous wave signals, chirp signals, control signals, management signals, reference signals, beacon signals, tones, pulses/impulses, waveforms associated with one or more communications protocols, and/or any other radio-frequency waveforms or signals. Wireless circuitry 24 is sometimes also referred to herein as wireless communications circuitry 24, wireless communication circuitry 24, communications circuitry 24, or simply as circuitry 24. Wireless circuitry 24 may include one or more antennas. Wireless circuitry 24 may also include baseband processor circuitry, transceiver circuitry, amplifier circuitry, filter circuitry, switching circuitry, radio-frequency transmission lines, and/or any other circuitry for transmitting and/or receiving radio-frequency signals using the antenna(s). Some or all of the components of wireless circuitry 24 may be disposed on, mounted to, communicatively coupled to, and/or integrated within the same substrate (e.g., a printed circuit board, semiconductor substrate, chip, integrated circuit (IC), IC packages, etc.) or may be distributed between two or more substrates (e.g., printed circuit boards, semiconductor substrates, chips, ICs, IC packages, etc.). Some or all of the signal generation, transmission, and/or reception operations described herein as being performed by wireless circuitry 24 may alternatively be performed by wired communications circuitry in input-output circuitry 20.

Wireless circuitry 24 may transmit and/or receive radio-frequency signals within a corresponding frequency band at radio frequencies (sometimes referred to herein as a communications band or simply as a “band”). The frequency bands handled by wireless circuitry 24 may include wireless local area network (WLAN) frequency bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), a Wi-Fi® 7 band, and/or other Wi-Fi® bands (e.g., from 1875-5160 MHz), wireless personal area network (WPAN) frequency bands such as the 2.4 GHz Bluetooth® band or other WPAN communications bands, cellular telephone frequency bands (e.g., bands from about 600 MHz to about 5 GHz, 3G bands, 4G LTE bands, 5G New Radio Frequency Range 1 (FR 1) bands below 10 GHz, 5G New Radio Frequency Range 2 (FR2) bands between 20 and 60 GHz, etc.), other centimeter or millimeter wave frequency bands between 10-100 GHz, sub-THz frequency bands between around 100 GHz and 10 THz (e.g., 6G bands), near-field communications (NFC) frequency bands (e.g., at 13.56 MHz), satellite navigation frequency bands (e.g., a GPS band from 1565 to 1610 MHz, a Global Navigation Satellite System (GLONASS) band, a BeiDou Navigation Satellite System (BDS) band, etc.), ultra-wideband (UWB) frequency bands that operate under the IEEE 802.15.4 protocol and/or other ultra-wideband communications protocols, satellite communications (satcom) bands (e.g., an IEEE C band (4-8 GHz), S band (2-4 GHz), L band (1-2 GHz), X band (8-12 GHz), W band (75-110 GHz), V band (40-75 GHz), K band (18-27 GHz), Kₐ band (26.5-40 GHz), Kᵤ band (12-18 GHz), etc.), unlicensed bands, communications bands under the family of 3GPP wireless communications standards, communications bands under the IEEE 802.XX family of standards, and/or any other desired frequency bands of interest. Different communications protocols may utilize different frequency bands for conveying radio-frequency signals. In some cases, two or more communications protocols may utilize one or more of the same frequency bands for conveying radio-frequency signals.

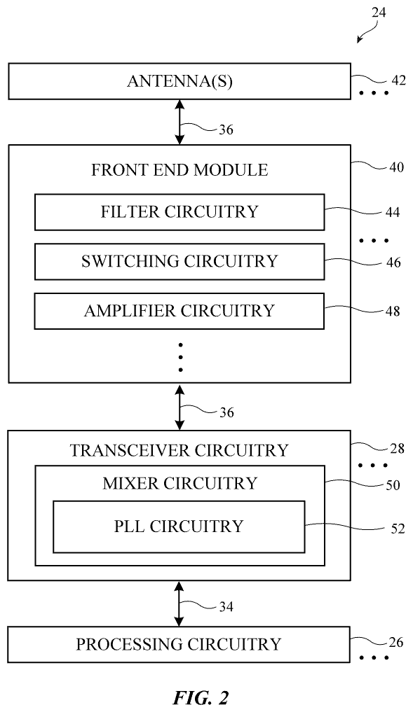

FIG. 2 is a diagram showing illustrative components within wireless circuitry 24. As shown in FIG. 2, wireless circuitry 24 may include processing circuitry 26, radio-frequency (RF) transceiver circuitry 28, radio-frequency front end circuitry such as radio-frequency front end (RFFE) module (FEM) 40, and antenna(s) 42. Processing circuitry 26 may include one or more baseband processors, application processors, general purpose processors, microprocessors, microcontrollers, digital signal processors, host processors, application specific signal processing hardware, and/or other types of processors. Processing circuitry 26 may be coupled to transceiver circuitry 28 over path 34. Transceiver circuitry 28 may be coupled to antenna 42 via radio-frequency transmission line path 36. Radio-frequency front end module 40 may be disposed on radio-frequency transmission line path 36 between transceiver circuitry 28 and antenna 42.

Transceiver circuitry 28 may include one or more transceivers. Each transceiver may include a transmitter and/or a receiver. In the example of FIG. 2, wireless circuitry 24 is illustrated as including only a single front end module 40 and a single antenna 42 for the sake of clarity. In general, wireless circuitry 24 may include any desired number of front end modules 40 and any desired number of antennas 42. If desired, processing circuitry 26 may be coupled to one or more transceivers in transceiver circuitry 28 over respective paths 34. Each transceiver may include a transmitter configured to output uplink signals to antenna 42 and/or a receiver configured to receive downlink signals from antenna 42. Each transceiver may be coupled to one or more antennas 42 over respective radio-frequency transmission line paths 36. Each radio-frequency transmission line path 36 may have a respective front end module 40 disposed thereon. If desired, two or more front end modules 40 may be disposed on the same radio-frequency transmission line path 36. If desired, one or more of the radio-frequency transmission line paths 36 in wireless circuitry 24 may be implemented without any front end module disposed thereon.

Radio-frequency transmission line path 36 may be coupled to an antenna feed on antenna 42. The antenna feed may, for example, include a positive antenna feed terminal and a ground antenna feed terminal. Radio-frequency transmission line path 36 may have a positive transmission line signal path that is coupled to the positive antenna feed terminal on antenna 42. Radio-frequency transmission line path 36 may have a ground transmission line signal path that is coupled to the ground antenna feed terminal on antenna 42. This example is illustrative and, in general, antennas 42 may be fed using any desired antenna feeding scheme. If desired, antenna 42 may have multiple antenna feeds that are coupled to one or more radio-frequency transmission line paths 36.

Radio-frequency transmission line path 36 may include transmission lines that are used to route radio-frequency antenna signals within device 10 (FIG. 1). Transmission lines in device 10 may include coaxial cables, microstrip transmission lines, stripline transmission lines, edge-coupled microstrip transmission lines, edge-coupled stripline transmission lines, transmission lines formed from combinations of transmission lines of these types, etc. Transmission lines in device 10 such as transmission lines in radio-frequency transmission line path 36 may be integrated into rigid and/or flexible printed circuit boards.

While performing wireless transmission, processing circuitry 26 may provide transmit signals (e.g., digital or baseband signals) to transceiver circuitry 28 over path 34. Transceiver circuitry 28 may further include circuitry for converting the transmit (baseband) signals received from processing circuitry 26. For example, transceiver circuitry 28 may include mixer circuitry 50 that up-converts (or modulates) the transmit (baseband) signals to radio frequencies prior to transmission over antenna 42. The example of FIG. 2 in which processing circuitry 26 communicates with transceiver circuitry 28 is illustrative. In general, transceiver circuitry 28 may communicate with a baseband processor, an application processor, general purpose processor, a microcontroller, a microprocessor, or one or more processors within processing circuitry 18 (FIG. 1). Transceiver circuitry 28 may also include digital-to-analog converter (DAC) and/or analog-to-digital converter (ADC) circuitry for converting signals between digital and analog domains. Transceiver circuitry 28 may include a transmitter that transmits the radio-frequency signals over antenna 42 via radio-frequency transmission line path 36 and front end module 40. Antenna 42 may transmit the radio-frequency signals to external wireless equipment by radiating the radio-frequency signals into free space.

While performing wireless reception, antenna 42 may receive radio-frequency signals from the external wireless equipment. The received radio-frequency signals may be conveyed to transceiver circuitry 28 via radio-frequency transmission line path 36 and front end module 40. Transceiver circuitry 28 may include circuitry a receiver that receives signals from front end module 40 and that converts the received radio-frequency signals into corresponding baseband signals. For example, mixer circuitry 50 in transceiver circuitry 28 may down-convert (or demodulate) the received radio-frequency signals to baseband frequencies prior to conveying the received signals to processing circuitry 26 over path 34.

Front end module (FEM) 40 may include radio-frequency front end circuitry that operates on the radio-frequency signals conveyed over radio-frequency transmission line path 36. FEM 40 may, for example, include front end module components such as radio-frequency filter circuitry 44 (e.g., low pass filters, high pass filters, notch filters, band pass filters, multiplexing circuitry, duplexer circuitry, diplexer circuitry, triplexer circuitry, etc.), switching circuitry 46 (e.g., one or more radio-frequency switches), radio-frequency amplifier circuitry 48 (e.g., one or more power amplifiers and/or one or more low-noise amplifiers), signal attenuators, impedance matching circuitry (e.g., circuitry that helps to match the impedance of antenna 42 to the impedance of radio-frequency transmission line 36), antenna tuning circuitry (e.g., networks of capacitors, resistors, inductors, and/or switches that adjust the frequency response of antenna 42), radio-frequency coupler circuitry, charge pump circuitry, power management circuitry, digital control and interface circuitry, and/or any other desired circuitry that operates on the radio-frequency signals transmitted and/or received by antenna 42. Each of the front end module components may be mounted to a common (shared) substrate such as a rigid printed circuit board substrate or flexible printed circuit substrate. If desired, the various front end module components may also be integrated into a single integrated circuit chip. If desired, amplifier circuitry 48 and/or other components in FEM 40 such as filter circuitry 44 may also be implemented as part of transceiver circuitry 28.

Filter circuitry 44, switching circuitry 46, amplifier circuitry 48, and other circuitry may be disposed along radio-frequency transmission line path 36, may be incorporated into FEM 40, and/or may be incorporated into antenna 42 (e.g., to support antenna tuning, to support operation in desired frequency bands, etc.). These components, sometimes referred to herein as antenna tuning components, may be adjusted (e.g., using control circuitry 14) to tune the frequency response and wireless performance of antenna 42 over time.

Transceiver circuitry 28 may be separate from front end module 40. For example, transceiver circuitry 28 may be formed on another substrate such as the main logic board of device 10, a rigid printed circuit board, or flexible printed circuit that is not a part of front end module 40. Although control circuitry 14 is shown separately from wireless circuitry 24 in the example of FIG. 1 for the sake of clarity, wireless circuitry 24 may include processing circuitry that forms a part of processing circuitry 18 and/or storage circuitry that forms a part of storage circuitry 16 of control circuitry 14 (e.g., portions of control circuitry 14 may be implemented on wireless circuitry 24). As an example, processing circuitry 26 and/or portions of transceiver circuitry 28 (e.g., a host processor on transceiver 28) may form a part of control circuitry 14. Control circuitry 14 (e.g., portions of control circuitry 14 formed on processing circuitry 26, portions of control circuitry 14 formed on transceiver 28, and/or portions of control circuitry 14 that are separate from wireless circuitry 24) may provide control signals (e.g., over one or more control paths in device 10) that control the operation of front end module 40.

Transceiver circuitry 28 may include wireless local area network transceiver circuitry that handles WLAN communications bands (e.g., Wi-Fi® (IEEE 802.11) or other WLAN communications bands) such as a 2.4 GHz WLAN band (e.g., from 2400 to 2480 MHz), a 5 GHz WLAN band (e.g., from 5180 to 5825 MHz), a Wi-Fi® 6E band (e.g., from 5925-7125 MHz), and/or other Wi-Fi® bands (e.g., from 1875-5160 MHz), wireless personal area network transceiver circuitry that handles the 2.4 GHz Bluetooth® band or other WPAN communications bands, cellular telephone transceiver circuitry that handles cellular telephone bands (e.g., bands from about 600 MHz to about 5 GHz, 3G bands, 4G LTE bands, 5G New Radio Frequency Range 1 (FR1) bands below 10 GHz, 5G New Radio Frequency Range 2 (FR2) bands between 20 and 60 GHz, 6G bands above 100 GHz, etc.), near-field communications (NFC) transceiver circuitry that handles near-field communications bands (e.g., at 13.56 MHz), satellite navigation receiver circuitry that handles satellite navigation bands (e.g., a GPS band from 1565 to 1610 MHz, a Global Navigation Satellite System (GLONASS) band, a BeiDou Navigation Satellite System (BDS) band, etc.), ultra-wideband (UWB) transceiver circuitry that handles communications using the IEEE 802.15.4 protocol and/or other ultra-wideband or impulse-based communications protocols, and/or any other desired radio-frequency transceiver circuitry for covering any other desired communications bands of interest.

Antenna 42 may be formed using any desired antenna structures. For example, antenna 42 may be an antenna with a resonating element that is formed from loop antenna structures, patch antenna structures, inverted-F antenna structures, slot antenna structures, planar inverted-F antenna structures, helical antenna structures, monopole antennas, dipoles, hybrids of these designs, etc. Two or more antennas 42 may be arranged into one or more phased antenna arrays (e.g., for conveying radio-frequency signals at millimeter wave frequencies). Parasitic elements may be included in antenna 42 to adjust antenna performance. Antenna 42 may be provided with a conductive cavity that backs the antenna resonating element of antenna 42 (e.g., antenna 42 may be a cavity-backed antenna such as a cavity-backed slot antenna).

The term “convey radio-frequency signals” as used herein means the transmission and/or reception of the radio-frequency signals (e.g., for performing unidirectional and/or bidirectional wireless communications with external wireless communications equipment). Antennas 42 may transmit the radio-frequency signals by radiating the radio-frequency signals into free space (or to free space through intervening device structures such as a dielectric cover layer). Antennas 42 may additionally, or alternatively, receive the radio-frequency signals from free space (e.g., through intervening devices structures such as a dielectric cover layer). The transmission and reception of radio-frequency signals by antennas 42 each involve the excitation or resonance of antenna currents on an antenna resonating element in the antenna by the radio-frequency signals within the frequency band(s) of operation of the antenna.

Communications circuitry in device 10 may include clock signal generation circuitry (sometimes also referred to as clocking circuitry or clock generation circuitry). The clock signal generation circuitry generates a clock signal that is used by the communications circuitry to transmit and/or receive other signals (e.g., radio-frequency signals). The clock signal generation circuitry may include, for example, local oscillator (LO) circuitry, voltage controlled oscillator (VCO) circuitry, digitally controlled oscillator (DCO) circuitry, and/or other types of clock circuitry. In implementations that are described herein, the clock signal generation circuitry may include phase locked loop (PLL) circuitry that generates a clock signal (sometimes referred to herein as output clock signal CLKout). The PLL circuitry may include one or more PLLs.

As shown in FIG. 2, for example, mixer circuitry 50 may include PLL circuitry 52 (e.g., within local oscillator circuitry of transceiver circuitry 28). PLL circuitry 52 may generate a clock signal that is used by mixer circuitry 50 to modulate (up-convert) transmitted signals from baseband to radio frequencies and/or to demodulate (down-convert) received signals from radio frequencies to baseband. If desired, mixer circuitry 50 may use the clock signal to up-convert and/or down-convert between baseband and intermediate frequencies and/or between intermediate frequencies and radio frequencies. While illustrated as forming a part of mixer circuitry 50 in FIG. 2 for the sake of simplicity, some or all of PLL circuitry 52 may be implemented within transceiver circuitry 28 but external to mixer circuitry 50 and/or may be implemented external to transceiver circuitry 28.

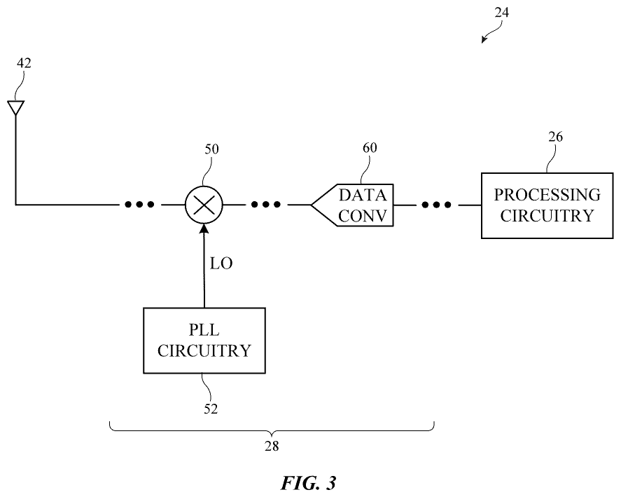

Implementations in which PLL circuitry 52 is included within wireless circuitry 24 and in which wireless circuitry 24 uses a clock signal generated by PLL circuitry 52 to convey radio-frequency signals over one or more antennas 42 are sometimes described herein as an example. This is illustrative and non-limiting. If desired, PLL circuitry 52 may be disposed external to wireless circuitry 24 and/or may be included within wired communications circuitry of device 10. If desired, the clock signal generated by PLL circuitry 52 (e.g., output clock signal CLKout) may be used by wireless circuitry 24 to convey radio-frequency signals between components within device 10 (e.g., over a radio-frequency connector or a wireless chip-to-chip interconnect) and/or may be used by wired communications circuitry in device 10 to convey a signal over a wired path within device 10 and/or between device 10 and an external device. FIG. 3 is a diagram of wireless circuitry 24 showing one example of how PLL circuitry 52 may supply a clock signal to mixer circuitry 50 for use in radio-frequency signal transmission and/or reception.

As shown in FIG. 3, transceiver circuitry 28 may be communicatively coupled between an antenna 42 and processing circuitry 26. If desired, one or more circuit components (e.g., circuits within front-end module 40 shown in FIG. 2 or other radio-frequency components) may be coupled between antenna 42 and transceiver circuitry 28. Similarly, one or more circuit components may be coupled between transceiver circuitry 28 and processing circuitry 26. Transceiver circuitry 28 may include mixer circuitry 50. Mixer circuitry 50 may include one or more mixers, one of which is shown in FIG. 3 for the sake of simplicity.

Mixer circuitry 50 may be configured to modulate (or demodulate) between a radio frequency and a baseband frequency or an intermediate frequency that is less than the radio frequency. Transceiver circuitry 28 may also include a data conversion circuit such as an analog-to-digital converter (ADC) and/or a digital-to-analog converter (DAC) configured to convert signals between an analog domain and a digital domain (e.g., signals interfacing with the mixers and/or antenna 42 are in the analog domain, whereas signals interfacing with processing circuitry 26 are in the digital domain). Mixer circuitry 50 may be configured to receive a clock signal such as local oscillator signal LO from PLL circuitry 52 (e.g., local oscillator signal LO of FIG. 3 may form an output clock signal CLKout of PLL circuitry 52). Mixer circuitry 50 may mix local oscillator signal LO with another signal to upconvert or downconvert the signal. PLL circuitry 52 of FIG. 3 may, for example, be included within a local oscillator signal generator for mixer circuitry 50. The example of FIG. 3 is illustrative and non-limiting.

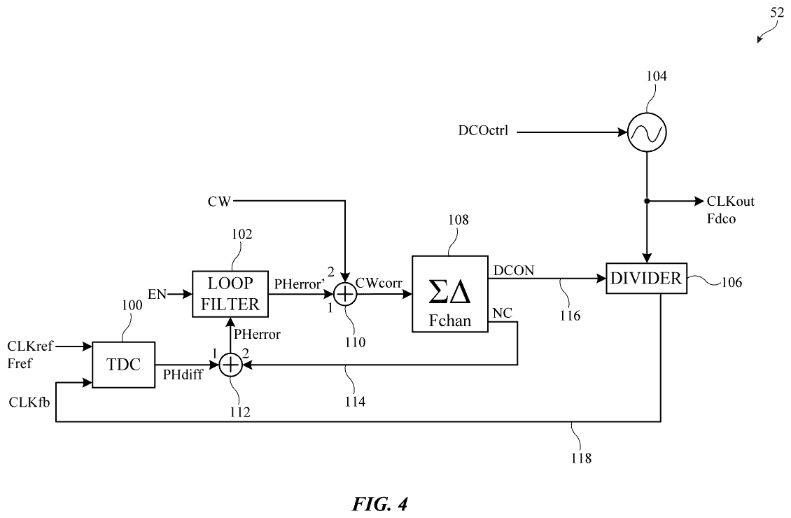

Phase-locked loop circuitry such as PLL circuitry 52 generates clock signals based on an input signal such as a reference clock signal. The clock signals generated by PLL circuitry 52 are phase locked to the input signal, which reduces phase error in the clock signals and can increase the stability of signal transmission or reception performed using the clock signals. FIG. 4 is a circuit diagram of PLL circuitry 52.

As shown in FIG. 4, PLL circuitry 52 may include time-do-digital converting circuitry such as time-to-digital converter (TDC) 100, loop filter circuitry such as loop filter 102 (e.g., a digital loop filter), variable oscillator circuitry such as digitally controlled oscillator (DCO) 104, and frequency division circuitry such as frequency divider 106. TDC 100 has a first input that receives a reference clock signal CLKref at frequency Fref (e.g., from a system clock, reference oscillator, crystal oscillator, or other clocking circuitry in device 10). DCO 104 has an output that is communicatively coupled to a first input of frequency divider 106. Frequency divider 106 has an output that is communicatively coupled to a second input of TDC 100 over feedback (loop) path 118.

During operation, DCO 104 generates output clock signal CLKout at a corresponding frequency Fdco based on a digital DCO control signal such as control signal DCOctrl (e.g., the magnitude of frequency Fdco may be given by the frequency of control signal DCOctrl and/or information/bits conveyed by control signal DCOctrl). DCO 104 may receive control signal DCOctrl from other control circuitry in device 10 (e.g., control circuitry 14 of FIG. 1). Control signal DCOctrl may, for example, configure DCO 104 to generate output clock signal CLKout at a selected frequency Fdco. Adjusting control signal DCOctrl may adjust the frequency Fdco of output clock signal CLKout. Frequency Fdco is sometimes also referred to herein as the clock frequency of PLL circuitry 52 or the clock frequency of output clock signal CLKout. PLL circuitry 52 may provide the output signal CLKout from DCO 104 to other circuitry in device 10 (e.g., measurement circuitry, wired communications circuitry, wireless circuitry 24, mixer circuitry 50 of FIGS. 2 and 3, etc.).

Frequency divider 106 receives output clock signal CLKout from DCO 104 at its first input. Frequency divider 106 may measure, sense, characterize, extract, or otherwise identify the frequency Fdco of the output clock signal CLKout produced by DCO 104 and may divide frequency Fdco and/or output clock signal CLKout according to a corresponding division ratio to produce a feedback clock signal CLKfb on feedback path 118 (e.g., at a corresponding frequency FB). TDC 100 receives feedback clock signal CLKfb from feedback path 118 via its second input. TDC 100 generates a digital signal PHdiff at its output that is proportional to the phase/time difference between reference clock signal CLKref and feedback clock signal CLKfb. TDC 100 may, for example, generate a digital signal PHdiff at its output that is proportional to the time interval between rising edges of the reference and feedback clock signals or between the falling edges of the reference and feedback clock signals. The digital signal PHdiff output by TDC 100 is sometimes also referred to herein as phase difference signal PHdiff, phase difference value PHdiff, or simply as phase difference PHdiff.

Frequency divider 106 may be a digital frequency divider such as, for example, a multi-modulus divider (MMD). Frequency divider 106 is therefore sometimes also referred to herein as MMD frequency divider 106 or simply as MMD 106. When implemented as an MMD, frequency divider 106 may be configured to divide an input frequency such as the frequency Fdco of output clock signal CLKout by one or more programmable integers. Unlike a fixed frequency divider, the MMD can dynamically switch between a range of division ratios based on a digital control signal DCON. In an ideal case, frequency Fdco should be equal to frequency Fref of reference clock signal CLKref after division by frequency divider 106 (e.g., the ideal division ratio used by frequency divider 106 may be the division ratio that causes frequency divider 106 to output feedback clock signal CLKfb at a frequency FB equal to frequency Fref).

PLL circuitry 52 may include digital modulator circuitry such as sigma delta (ΣΔ) modulator 108. Sigma delta modulator (SDM) 108 can sometimes also be referred to as a delta sigma (ΔΣ) modulator (DSM). Sigma delta modulator 108 may generate digital control signal DCON and may provide digital control signal DCON to a second input of frequency divider 106 over digital control path 116 (sometimes also referred to herein as SDM path 116 or SDM output path 116). Sigma delta modulator 108 may output digital control signal DCON as a time-varying bitstream (e.g., a bit stream with some pattern of logic ones and zero) for adjusting the division ratio of frequency divider 106 in real time. Sigma delta modulator 108 may operate at a corresponding channel frequency Fchan.

The output of TDC 100 may be communicatively coupled to a first input (1) of signal combiner 112. Sigma delta modulator 108 may have a first output coupled to digital control path 116. Sigma delta modulator 108 may have a second output communicatively coupled to a second input (2) of signal combiner 112 over a digital path such as noise cancellation path 114. Signal combiner 112 may have an output communicatively coupled to the input of loop filter 102. During operation, sigma delta modulator 108 may also generate a digital control signal such as noise cancellation signal NC on noise cancellation path 114. Signal combiner 112 may receive phase difference signal PHdiff from the output of TDC 100 at its first input. Signal combiner 112 may receive noise cancellation signal NC (sometimes referred to as noise cancelling information) from sigma delta modulator 108 and noise cancellation path 114 at its second input.

Signal combiner 112 may combine noise cancellation signal NC with phase difference signal PHdiff to produce a digital signal such as phase error signal PHerror. Signal combiner 112 may include, for example, a digital adder or subtractor circuit that subtracts noise cancellation signal NC from phase difference signal PHdiff to produce phase error signal PHerror. Phase error signal PHerror may identify or characterize the measured phase error between reference clock signal CLKref and feedback clock signal CLKfb (e.g., as measured by TDC 100). Phase error signal PHerror is sometimes also referred to herein as phase offset signal PHerror or simply as phase error PHerror.

In some implementations, a loop filter is coupled between the output of signal combiner 112 and the control input of DCO 104, closing a loop path of PLL circuitry 52 from the output of TDC 100 to the control input of DCO 104. Put differently, a loop path is established from the output of DCO 104, through frequency divider 106, feedback path 118, TDC 100, and the loop filter back to the control input of DCO 104 (e.g., where the loop path loops around or bypasses sigma delta modulator 108). In these implementations, the loop filter receives a digital control signal that sets the frequency Fdco produced by DCO 104 close to a desired frequency (channel). The loop filter then modifies the digital control signal using phase error signal PHerror, producing a corrected control signal that is supplied to DCO 104 (e.g., as control signal DCOctrl). At the same time, sigma delta modulator 108 is configured using a digital control signal that identifies a corresponding channel word CW. Channel word CW represents a particular divider ratio for sigma delta modulator 108 and is sometimes also referred to herein as divider ratio CW or division ratio CW. Sigma delta modulator 108 generates the digital control signal DCON used to control frequency divider 106 based on the current channel word CW (e.g., by multiplying frequency Fref of reference clock signal CLKref by the current channel word CW).

In these implementations, channel word CW is held constant and the control signal DCOctrl provided to DCO 104 is varied based on the measured phase error to lock the PLL circuitry. Put differently, the PLL circuitry is locked by dynamically controlling the setting/configuration of DCO 104 (e.g., via the loop filter) and/or other parameters influencing its frequency Fdco to lock the phase of feedback clock signal CLKfb and therefore also output clock signal CLKout to a reference phase while the channel word CW input to the sigma delta modulator is held constant. However, it may sometimes be desirable to freely run DCO 104 without continuously controlling its settings/configuration (e.g., without varying, changing, or adjusting control signal DCOctrl) but while still keeping the phase of feedback clock CLKfb aligned with reference clock CLKref to allow TDC 100 to continue operating (e.g., by keeping the phase difference between feedback clock CLKfb and reference clock CLKref within the measurement range of TDC 100).

To mitigate these issues, PLL circuitry 52 may be locked by dynamically controlling the phase of sigma delta modulator 108 via adjustment to the channel word provided to the sigma delta modulator (e.g., to match frequency Fdco) while keeping the setting/configuration of DCO 104 (e.g., control signal DCOctrl) constant. The implementation of PLL circuitry 52 shown in FIG. 4 illustrates one such example of how PLL circuitry 52 may be locked by dynamically adjusting the channel word provided to sigma delta modulator 108 while DCO 104 runs with a constant setting/configuration over time (e.g., where the SDM-programmed channel frequency Fchan is adjusted to the frequency Fdco of DCO 104). This may configure PLL circuitry 52 to perform closed loop operations and lock while DCO 104 remains free running. This may, for example, allow other components in device 10 (e.g., measurement circuitry) to perform measurements of the free-running DCO such as TDC-based frequency measurements (e.g., for characterizing the performance of DCO 104, performing long DCO frequency measurements, performing interference measurements, etc.) that would not otherwise be possible in scenarios where the PLL circuitry is locked via dynamic adjustment to the setting/configuration of DCO 104.

As shown in FIG. 4, rather than including a loop path from the output of DCO 104 to the control input of DCO 104, PLL circuitry 52 instead includes a loop path from the output of frequency divider 106 to the second input of frequency divider 106 through feedback path 118, TDC 100, signal combiner 112, loop filter 102, signal combiner 110, and sigma delta modulator 108. Signal combiner 110 (e.g., a digital adder or subtractor) may have a first input (1) communicatively coupled to the output of loop filter 102 (e.g., loop filter 102 may be coupled between the output of signal combiner 112 and the first input of signal combiner 110). Signal combiner 110 may have a second input (2) that receives a digital control signal that includes or otherwise identifies the current channel word CW for PLL circuitry 52. The output of signal combiner 110 may be communicatively coupled to the input of sigma delta modulator 108.

If desired, loop filter 102 may be selectively enabled or disabled by an associated loop filter enable signal EN (e.g., received from control circuitry 14 of FIG. 1). When enable signal EN is asserted (e.g., driven to a logic “1”), loop filter 102 may be switched into use or activated to close the loop of PLL circuitry 52 (e.g., placing the PLL circuitry in a closed loop state, mode, or configuration). When enable signal EN is deasserted (e.g., driven to a logic “0”), loop filter 102 may be switched out of use or deactivated to open the loop of PLL circuitry 52 (e.g., placing the PLL circuitry in an open loop state, mode, or configuration). Loop filter 102 may include, as examples, a P-type loop filter, a PI-type loop filter, a PID-type loop filter, or another type of loop filter (e.g., depending on phase behavior requirements).

After the loop has been closed, PLL circuitry 52 may generate output clock signal CLKout at frequency Fdco while ensuring that the phase difference (phase error) between clock signals CLKref and CLKfb at the inputs of TDC 100 are minimized, fixed to some non-zero phase value, or otherwise controlled. In general, frequency Fdco (sometimes also referred to herein as PLL output frequency Fdco or output clock frequency Fdco) is equal to Fref*N, where N is the frequency division factor of frequency divider 106. For example, frequency division factor N of frequency divider 106 may be an integer that is greater than 10, greater than 20, greater than 40, greater than 60, greater than 80, 20-100, 80-120, 60-140, or at least 100. Reference clock frequency Fref may be in the Megahertz or Gigahertz frequency range (e.g., Fref may be 1-10 MHz, 10-100 MHz, at least 100 MHz, 100 MHz to 1 GHz, less than 1 GHz, 0.1 GHz, 0.5 GHz, 0.1-1 GHz, etc.). Thus, in an example where reference clock frequency Fref is equal to 80 MHz and the division factor N is equal to 100, the output clock frequency Fdco will be equal to 8 GHz (i.e., 80 MHz multiplied by 100). A phase-locked loop implemented using time-to-digital converter (TDC) 100, loop filter 102, and DCO 104 is sometimes referred to as a “digital” phase-locked loop (e.g., PLL circuitry 52 may sometimes also be referred to as digital PLL circuitry 52).

In some embodiments, digital PLL circuitry 52 may be a “fractional” phase-locked loop. As an example, a fractional PLL might be able to generate output clock signals having frequencies equal to 12.5*Fref, 12.4*Fref, 12.3*Fref, 12.2*Fref, 12.1*Fref, 12.01* Fref, 12.001*Fref, 12.0001*Fref, etc. This type of phase-locked loop in which the PLL is not limited to any step size (raster) and can theoretically support an infinite number of channels is defined as a “full-fractional” PLL. As another example, a fractional PLL may be configured to generate clock signals having frequencies equal to 12*Fref, 12.25*Fref, 12.50*Fref, and 12.75*Fref. In this example, the step size (PLL raster) is equal to 0.25*Fref, and the number of channels is equal to four. This type of phase-locked loop in which the step size or raster is some predetermined fraction of Fref is defined as a “partial-fractional” PLL. This example in which the partial-fractional PLL has four channels is illustrative and non-limiting. Partial-fractional PLLs may have 2 channels, 4 channels, 8 channels, 16 channels, 32 channels, or in general 2\hat{ }N number of channels where N is an integer equal to or greater than one. Partial-fractional PLLs may offer a finer frequency control relative to integer PLLs, for example.

It is generally desirable to have a precise feedback clock signal CLKfb to start with a small phase error relative to the reference clock signal CLKref. A larger starting phase error between clock signals CLKref and CLKfb results in a longer convergence time for PLL circuitry 52 (e.g., taking longer for the phase error to settle within some locking criteria). In practice, the initial phase of feedback clock signal CLKfb may be subject to various uncertainties before the loop is closed. For example, PLL circuitry 52 may start DCO 104 in some arbitrary clock phase relative to reference clock signal CLKref and, in the case of a fractional PLL, the phase of feedback clock CLKfb may continuously change over time between DCO 104 being enabled and the loop closing. There is no expected DCO phase when the loop is being closed. Moreover, there may be uncertainty with frequency divider 106 being activated due to synchronization issues between different clock domains associated with clock signals CLKref and CLKout, due to frequency divider 106 and sigma delta modulator 108 running in different clock domains. Due to these uncertainties, the phase of feedback clock signal CLKfb output from frequency divider 106 can be unpredictable but is expected to start in a certain range within a couple of DCO clock cycles.

The division ratio represented by channel word CW may have a fractional (non-integer) value that is a function of division factor N. TDC unit delay may be a number representing an average resolution or granularity of TDC 100, expressed in units of time. The TDC unit delay might not exactly match the actual physical value of the TDC resolution, which can vary as a function of temperature and/or analog mismatch. The phase alignment coefficient, sometimes referred to as a phase correction coefficient, can be equal to a product of the division ratio and the TDC unit delay values. The phase alignment coefficient can thus have a frequency dependent value. The phase alignment coefficient is generally a static value, which can optionally be computed in advance and saved into a non-volatile memory component. The phase alignment coefficient may be, for example, a MASH Noise Canceling (MNC) Coefficient that provides scaling between the TDC measurement (in TDC delay units) and the fractional interpretation in the MASH (angle/DCO period). This coefficient is dependent on both TDC unit delay and CW.

During operation, signal combiner 112 may generate (e.g., produce, output, compute, calculate, etc.) phase error signal PHerror by combining the phase difference signal PHdiff output by TDC 100 with the noise cancellation signal NC output by sigma delta modulator 108 (e.g., by calculating a sum of phase difference signal PHdiff and the noise cancellation signal NC or by subtracting noise cancellation signal NC from phase difference signal PHdiff). Signal combiner 112 is sometimes also referred to as a combiner 112, adder 112, subtractor 112, summing circuit 112, or subtraction circuit 112.

When the loop is closed, loop filter 102 may generate a digital signal such as filtered phase error signal PHerror′ (e.g., a filtered binary code) by filtering the phase error signal PHerror generated by signal combiner 112. Loop filter 102 may supply filtered phase error signal PHerror′ to the first input of signal combiner 110. Signal combiner 110 may generate a digital signal that includes or identifies a phase-error corrected channel word CWcorr (e.g., by adding filtered phase error signal PHerror′ to the uncorrected channel word CW). Corrected channel word CWcorr represents a compensated division ratio that has been adjusted based on the phase error as measured by TDC 100. Signal combiner 110 is sometimes also referred to as a combiner 110, adder 110, or summing circuit 110. Signal combiner 110 may supply corrected channel word CWcorr to sigma delta modulator 108. Sigma delta modulator 108 may use corrected channel word CWcorr to generate/update the digital control signal DCON used to control frequency divider 106 and/or to generate/update noise cancellation signal NC. Corrected channel word CWcorr is sometimes also referred to herein as corrected divider ratio CWcorr, corrected division ratio CWcorr, phase error corrected division ratio CWcorr, or phase error corrected channel word CWcorr. Sigma delta modulator 108 may adjust the digital control signal DCON that is provided to frequency divider 106 based on corrected channel word CWcorr. In other words, frequency divider 106 may be adjusted by sigma delta modulator 108 based on corrected channel word CWcorr and thus the phase error measured by TDC 100. Locking PLL circuitry 52 in this way may allow DCO 104 to remain free-running (e.g., using a constant setting or configuration).

The example of FIG. 4 is illustrative and non-limiting. If desired, phase error correction may be applied at the input of sigma delta modulator 108 (as shown in the embodiment of FIG. 4) or may alternatively be applied at the output of sigma delta modulator 108. Applying the phase correction at the input side of sigma delta modulator 108 allows any phase adjustment to be fractions of the DCO clock cycle. This might be advantageous for fractional PLLs. Conversely, applying the phase correction at the output side of sigma delta modulator 108 may restrict the correction to integer-only phase adjustments, which might be suitable for integer PLLs. Signal combiner 112, loop filter 102, signal combiner 110, sigma delta modulator 108, and frequency divider 106 may include any desired digital circuitry, digital logic gates, etc. If desired, the operations of signal combiner 112 and noise cancellation path 114 may be incorporated into the filter characteristic of loop filter 102. Measurement circuitry may perform measurements of the DCO based directly on the TDC output, which remains in range while the PLL Is locked.

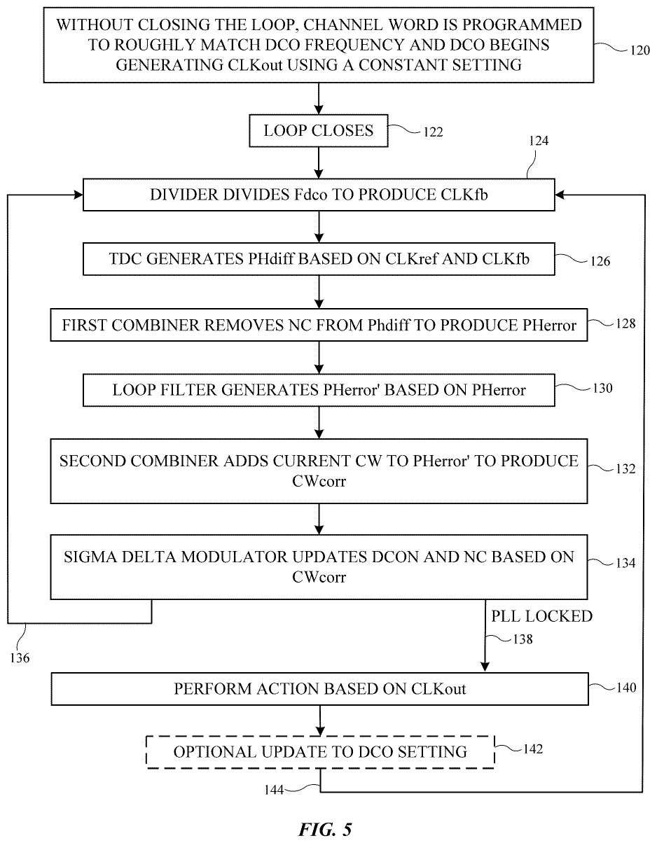

Operations of PLL circuitry 52 are described in further detail in connection with the flow chart of FIG. 5. At operation 120 of FIG. 5, PLL circuitry 52 is in an open loop state (e.g., operation 120 may be performed prior to closing the loop of PLL circuitry 52). DCO control signal DCOctrl may configure DCO 104 to begin generating output clock signal CLKout at a corresponding frequency Fdco. DCO 104 may remain in this setting/configuration and may continue to generate output clock signal CLKout prior to, concurrent with, and/or after the remaining operations of FIG. 5 (e.g., DCO control signal DCOctrl may be constant, without changing values, prior to, concurrent with, and after operations 122-140 of FIG. 5).

At the same time, control circuitry may supply a channel word CW to PLL circuitry 52 that is selected to roughly match the frequency Fdco output by DCO 104. In other words, the channel word CW provided to PLL circuitry 52 may be programmed and provided to signal combiner 110 according to the equation CW*Fref=Fchan≈Fdco. This may serve to keep the frequency FB of feedback clock signal CLKfb within the measurement range of TDC 100 prior to closing the loop. Because the loop has not yet closed (e.g., loop filter 102 is disabled), signal combiner 110 passes channel word CW to sigma delta modulator 108 without combining the channel word with a filtered phase error signal (e.g., the corrected channel word CWcorr provided to sigma delta modulator 108 is equal to channel word CW and has not yet been corrected using a measured phase error). Put differently, loop filter 102 does not perform phase error correction on channel word CW while the loop is open. Sigma delta modulator 108 generates digital control signal DCON based on channel word CW. Sigma delta modulator 108 may run at channel frequency Fchan =CW*Fref while generating digital control signal DCON.

At operation 122, the loop in PLL circuitry 52 closes. For example, loop filter 102 may be activated and switched into use between signal combiners 110 and 112. Once the loop has closed, TDC 100 may begin measuring phase error between feedback clock signal CLKfb and reference clock CLKref. Loop filter 102 may then begin using the measured phase error to correct the channel word CW supplied to sigma delta modulator 108 to lock PLL circuitry 52 while the configuration/setting of DCO 104 remains constant (e.g., without adjusting control signal DCOctrl).

For example, at operation 124, frequency divider 106 may divide the frequency Fdco of output clock signal CLKout (e.g., in variable integer steps) to produce feedback clock signal CLKfb at a corresponding frequency FB. Frequency divider 106 may perform this division based on the digital control signal DCON received from sigma delta modulator 108 (e.g., based on the uncorrected channel word CW during a first iteration of operation 124 after closing the loop and using a corrected channel word CWcorr during subsequent iterations). In general, the output of sigma delta modulator 108 (e.g., digital control signal DCON) may be equal to the time average of average of Fdco divided by Fref or, equivalently, channel word CW.

Just after closing the loop, the starting phase of feedback clock signal CLKfb may drift (e.g., may exhibit non-zero phase error) due to mismatch between the initial channel frequency Fchan of sigma delta modulator 108 and the real frequency Fdco of DCO 104. At operation 126, TDC 100 may measure this drift (phase error) by generating phase difference signal PHdiff based on reference clock signal CLKref and feedback clock signal CLKfb. The phase difference signal PHdiff generated by TDC 100 may be equal to the difference between the phase of reference clock signal CLKref and the phase of feedback clock signal CLKfb.

At operation 128, the second input of signal combiner 112 may receive noise cancellation signal NC from sigma delta modulator 108 via noise cancellation path 114. The first input of signal combiner 112 may receive phase difference signal PHdiff from TDC 100. Signal combiner 112 may generate phase error signal PHerror based on phase difference signal PHdiff and noise cancellation signal NC (e.g., by subtracting noise cancellation signal NC from phase difference signal PHdiff). Noise cancellation signal NC may represent a phase that is expected by sigma delta modulator 108.

At operation 130, signal combiner 112 may feed phase error signal PHerror to loop filter 102. Loop filter 102 may filter phase error signal PHerror to generate filtered phase error signal PHerror'. Loop filter 102 may transmit filtered phase error signal PHerror′ to the first input of signal combiner 110.

At operation 132, the second input of signal combiner 110 may receive channel word CW. The first input of signal combiner 110 may receive filtered phase error signal PHerror′ from loop filter 102. Signal combiner 110 may combine, modify, adjust, correct, tweak, tune, alter, or otherwise modify channel word CW with/using phase error signal PHerror′ to produce corrected channel word CWcorr (e.g., by adding phase error signal PHerror′ to channel word CW or by subtracting phase error signal PHerror′ from channel word CW). Corrected channel word CWcorr corresponds to the factor between the frequency Fdco of DCO 104 and the frequency Fref of reference clock CLKref. Signal combiner 110 may transmit corrected channel word CWcorr to the input of sigma delta modulator 108.

At operation 134, sigma delta modulator 108 may update the control signal DCON supplied to frequency divider 106 and the division ratio of frequency divider 106 based on corrected channel word CWcorr and thus the measured phase error of feedback clock signal CLKfb. This may effectively change the magnitude of the channel frequency Fchan of sigma delta modulator 108 relative to before the loop was closed (e.g., changing the operating frequency of sigma delta modulator 108 from Fchan=CW*Fref to Fchan=CWcorr*Fref). This may serve to control the phase of sigma delta modulator 108 and its output (e.g., digital control signal DCON) to align to frequency Fdco of DCO 104.

In general, the phase of feedback clock signal CLKfb has a constant relation with the integrated phase of sigma delta modulator 108. The sigma delta modulator may translate a fractional channel word (e.g., corrected channel word CWcorr) to a series of integer MMD divider values included within or otherwise identified by digital control signal DCON. If desired, sigma delta modulator 108 may also update the noise cancellation signal NC provided to signal combiner 112 based on corrected channel word CWcorr. Noise cancellation signal NC may, for example, represent the residual/fractional phase of the feedback clock signal. Because the MMD in frequency divider 108 can only operate on an integer output from the sigma delta modulator, noise cancellation signal NC may be a residual value that represents the difference between the reference phase of the sigma delta modulator and the actual phase of feedback clock signal CLKfb. If desired, sigma delta modulator 108 may periodically change the MMD division ratio of frequency divider 106 over time (e.g., on average, the MMD division ratio of frequency divider 106, which may only be an integer value, may correspond to the corrected channel word CWcorr).

If/when PLL circuitry 52 has not yet locked (e.g., the channel frequency Fchan of sigma delta modulator 108 has not sufficiently aligned/locked to frequency Fdco and/or the phase of feedback clock signal CLKfb has not sufficiently aligned/locked to the phase of reference clock CLKref), processing may loop back to operation 124 via path 136. PLL circuitry 52 may continue to iterate over operations 124-134 until the PLL circuitry has locked. If/when PLL circuitry 52 has locked (e.g., the channel frequency Fchan of sigma delta modulator 108 has aligned/locked to frequency Fdco and the phase of feedback clock signal CLKfb has aligned/locked to the phase of reference clock CLKref), processing may proceed from operation 134 to operation 140 via path 138.

At operation 140, device 10 may perform one or more actions using the locked PLL circuitry 52 and/or based on the output clock signal CLKout produced by PLL circuitry 52 while locked. As one example, measurement circuitry in device 10 may perform one or more measurements of output clock signal CLKout and/or the output of TDC 100. The measurements may include, for example, measurements of DCO 104 in a free-running state that would not otherwise be possible when the loop filter is coupled to the control input of DCO 104, such as measurements of frequency Fdco over relatively long time periods, interference measurements, measurements characterizing the free-running performance of DCO 104, etc. If desired, device 10 may perform pass/fail testing on DCO 104 using the measurements or may identify and/or execute one or more configuration/setting adjustments to make on DCO 104, using control signal DCOctrl, that improve or optimize the measured performance of DCO 104. As another example, communications circuitry in device 10 may use output clock signal CLKout to transmit and/or received signals. For example, wired communications circuitry may use output clock signal CLKout to transmit and/or receive high frequency signals over a wired link. As another example, PLL circuitry 52 may supply output clock signal CLKout to mixer circuitry 50 in wireless circuitry 24 (FIGS. 2 and 3) for use in conveying signals.

At optional operation 142, control circuitry may update the configuration/setting of DCO 104 (e.g., by adjusting or changing the value of control signal DCOctrl). This may occur, for example, when there is a change in an operating parameter of PLL circuitry 52 such as temperature, supply voltage, flicker noise, etc., and/or when device 10 needs output clock signal CLKout to be provided at a different frequency Fdco. When this update occurs, processing may loop back to operation 124 via path 144 and the controlled loop in PLL circuitry 52 may follow the change without needing to open the loop (e.g., if/when the change is not too large). This may also facilitate long measurements of DCO 104 (e.g., at operation 140) even as the parameters of the DCO change over time. Operation 142 may be omitted if desired. If desired, the PLL circuitry may continue to perform the control loop of operations 124-136 (e.g., looping back via path 138) concurrent with performing operations 140 and/or 142. This may help to mitigate situations where the channel word is unstable, which can produce flicker noise of the DCO that may cause frequency Fdco to vary naturally over time. Any updates from the control loop and produced in frequency Fdco due to flicker noise can then be considered while processing each iteration of operation 140.

The operations of FIG. 5 are illustrative and non-limiting. In some embodiments, one or more of the described operations may be modified, replaced, or omitted. In some embodiments, one or more of the described operations may be performed in parallel. In some embodiments, additional processes may be added or inserted between the described operations. If desired, the order of certain operations may be reversed or altered and/or the timing of the described operations may be adjusted so that they occur at slightly different times. In some embodiments, the described operations may be distributed in a larger system.

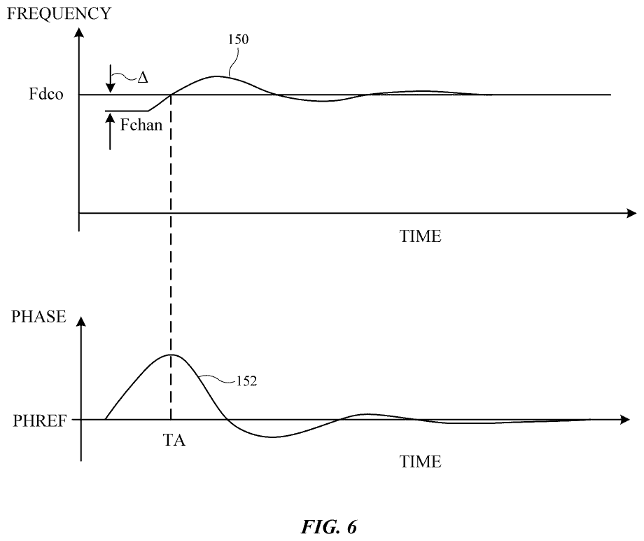

FIG. 6 is a timing diagram illustrating how PLL circuitry 52 may be locked while processing the operations of FIG. 5. Curve 150 of FIG. 6 plots the channel frequency Fchan of sigma delta modulator 108 over time. Curve 150 is sometimes also referred to as frequency waveform 150. Curve 152 of FIG. 6 plots the phase of feedback clock signal CLKfb (e.g., as controlled by sigma delta modulator 108 via the digital control signal DCON supplied to frequency divider 106 and generated based on corrected channel word CWcorr). Curve 152 is sometimes also referred to as phase waveform 152.

As shown by curve 150, channel frequency Fchan may be constant prior to closing the loop in PLL circuitry 52. During this time, channel frequency Fchan may be set to roughly approximate the frequency Fdco of DCO 104 (e.g., via the programming of channel word CW at operation 120 of FIG. 5). This may, for example, help to ensure that feedback clock signal CLKfb is within the measurement range of TDC 100 given reference clock signal CLKref once the loop is closed. However, in practice, channel frequency Fchan may differ from frequency Fdco by a small margin Δ during this time.

When the loop in PLL circuitry 52 closes, there may be a non-zero phase error in feedback clock signal CLKfb, illustrated by curve 152 exceeding the constant phase PHREF of reference clock signal CLKref while channel frequency Fchan (curve 150) is constant. The phase PHREF of reference clock signal CLKref is sometimes also referred to herein as reference phase PHREF. When the loop in PLL circuitry 52 closes (e.g., at operation 122 of FIG. 5), TDC 100 begins measuring the difference between the phase of feedback clock signal CLKfb and the phase PHREF of reference clock signal CLKref, loop filter 102 begins a supplying the corresponding filtered phase error signal PHerror′ to signal combiner 110, and signal combiner 110 begins supplying corrected channel word CWcorr to sigma delta modulator 108 instead of the uncorrected channel word CW supplied to the modulator prior to closing the loop.

The corrected channel word CWcorr supplied to sigma delta modulator 108 may change the channel frequency Fchan of sigma delta modulator 108 (e.g., according to the equationFchan =CWcorr*Fref), illustrated by curve 150 beginning to increase from its constant value prior to time TA. Once channel frequency Fchan crosses frequency Fdco of DCO 104 at time TA, the phase of feedback clock signal CLKfb begins to decrease, as shown by curve 152. The corresponding change in measured phase error (e.g., as represented in filtered phase error signal PHerror') may effectively adjust the value of the corrected channel word CWcorr supplied to sigma delta modulator 108 in a manner that begins to pull channel frequency Fchan back down towards frequency Fdco. This process may continue as PLL circuitry 52 loops through its loop path (e.g., as PLL circuitry 52 iterates through operations 124-134 of FIG. 5) until the channel frequency Fchan of sigma delta modulator 108 converges (settles) upon or aligns with (locks to) the frequency Fdco of DCO 104 and the phase of feedback clock signal CLKfb converges (settles) upon or aligns with (locks to) the phase PHREF of reference clock signal CLKref. PLL circuitry 52 is locked at and after this time (e.g., processing may proceed from operation 134 to operation 140 of FIG. 5).

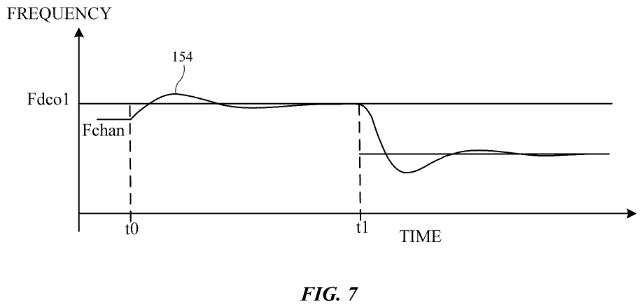

FIG. 7 illustrates another example of how the controlled loop in PLL circuitry 52 may follow a change in the setting/configuration of DCO 104 (e.g., after performing optional operation 142 of FIG. 5). Curve 154 plots the channel frequency Fchan of sigma delta modulator 108 in this type of situation. During the time period prior to time t1, control signal DCOctrl may be supplied to DCO 104 with a first constant value, which places DCO 104 in a first configuration/setting that remains constant until time t1. When configured using the first configuration/setting, DCO 104 may generate output clock signal CLKout at a first frequency Fdco1. As shown by curve 154, by looping through operations 124-134 of FIG. 5 beginning at time t0, PLL circuitry 52 may lock the channel frequency Fchan of sigma delta modulator 108 to frequency Fdco1 prior to time t1.

At time t1, control signal DCOctrl may be supplied to DCO 104 with a second constant value, which places DCO 104 in a second configuration/setting that remains constant after time t1. When configured using the second configuration/setting, DCO 104 may generate output clock signal CLKout at a second frequency Fdco2. As shown by curve 154, by looping through operations 124-134 of FIG. 5 beginning at time t1, PLL circuitry 52 may lock the channel frequency Fchan of sigma delta modulator 108 to frequency Fdco2 after time t1. When frequency Fdco2 is sufficiently close to frequency Fdco1, PLL circuitry 52 may lock to frequency Fdco1 and to frequency Fdco2 after time t0 without opening or restarting the loop. PLL circuitry 52 that includes digital phase alignment circuit components configured and operated as described herein may be technically advantageous and beneficial by allowing for relatively long DCO measurements while DCO remains free-running and/or by enabling significantly faster locking times, which can also provide power savings by allowing slower reference clock frequencies while meeting lock and re-lock timing requirements. Shorter lock times can also allow optimization of more PLL off times.

If desired, PLL circuitry 52 may include an additional loop filter coupled between signal combiner 112 and the control input of DCO 104. The additional loop filter may supply control signal DCOctrl to DCO 104. In these implementations, PLL circuitry 52 may be locked using any desired combination of updates to channel word CWcorr by loop filter 102 (e.g., as outlined in FIGS. 4-7) and adjustments to the control signal DCOctrl supplied to DCO 104 by the additional loop filter (e.g., DCO 104 need not remain in a constant configuration/setting).

The methods and operations described above in connection with FIGS. 1-7 may be performed by the components of device 10 using software, firmware, and/or hardware (e.g., dedicated circuitry or hardware). Software code for performing these operations may be stored on non-transitory computer readable storage media (e.g., tangible computer readable storage media) stored on one or more of the components of device 10 (e.g., storage circuitry 16 and/or wireless circuitry 24 of FIG. 1). The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by processing circuitry on one or more of the components of device 10 (e.g., processing circuitry in wireless circuitry 24, processing circuitry 18 or control circuitry 14 of FIG. 1, etc.). The processing circuitry may include microprocessors, application processors, digital signal processors, central processing units (CPUs), application-specific integrated circuits with processing circuitry, or other processing circuitry.

As used herein, the term “concurrent” means at least partially overlapping in time. In other words, first and second events are referred to herein as being “concurrent” with each other if at least some of the first event occurs at the same time as at least some of the second event (e.g., if at least some of the first event occurs during, while, or when at least some of the second event occurs). First and second events can be concurrent if the first and second events are simultaneous (e.g., if the entire duration of the first event overlaps the entire duration of the second event in time) but can also be concurrent if the first and second events are non-simultaneous (e.g., if the first event starts before or after the start of the second event, if the first event ends before or after the end of the second event, or if the first and second events are partially non-overlapping in time). As used herein, the term “while” is synonymous with “concurrent.”

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is illustrative and various modifications can be made to the described embodiments. The foregoing embodiments may be implemented individually or in any combination.

What is claimed is:

1. Phase-locked loop (PLL) circuitry comprising:
a time-to-digital converter (TDC), wherein a first input of the TDC is configured to receive a reference clock signal;
a frequency divider, wherein an output of the frequency divider is communicatively coupled to a second input of the TDC;
a sigma delta modulator (SDM), wherein a first output of the SDM is communicatively coupled to a first input of the frequency divider; and
a loop filter communicatively coupled between an output of the TDC and an input of the SDM.

2. The PLL circuitry of claim 1, further comprising:
a digitally controlled oscillator (DCO) communicatively coupled to a second input of the frequency divider.

3. The PLL circuitry of claim 2, further comprising:
a first signal combiner, wherein a first input of the first signal combiner is communicatively coupled to the output of the TDC, a second input of the first signal combiner is communicatively coupled to a second output of the SDM, and an output of the first signal combiner is communicatively coupled to an input of the loop filter.

4. The PLL circuitry of claim 3, further comprising:
a second signal combiner, wherein a first input of the second signal combiner is communicatively coupled to an output of the loop filter, a second input of the second signal combiner is configured to receive a channel word, and an output of the second signal combiner is communicatively coupled to the input of the SDM.

5. The PLL circuitry of claim 4, wherein the SDM is configured to supply a digital control signal to the frequency divider that controls a division ratio of the frequency divider.

6. The PLL circuitry of claim 5, wherein:
the DCO is configured to generate an output clock signal at an output frequency,
the frequency divider is configured to generate a feedback clock signal based on the output clock signal and the division ratio, and
the TDC is configured to generate a phase difference signal based on the reference clock signal and the feedback clock signal.

7. The PLL circuitry of claim 6, wherein:
the first signal combiner is configured to generate a phase error signal based on the phase difference signal and a noise cancellation signal received from the second output of the SDM, and
the loop filter is configured to generate a filtered phase error signal based on the phase error signal.

8. The PLL circuitry of claim 7, wherein:
the second signal combiner is configured to generate a corrected channel word based on the channel word and the filtered phase error signal,
the SDM is configured to update the noise cancellation signal based on the corrected channel word, and
the SDM is configured to update the digital control signal and the division ratio of the frequency divider based on the corrected channel word.

9. The PLL circuitry of claim 8, wherein:
the DCO is configured to generate the output clock signal based on a digital control signal,
the PLL circuitry is configured to lock by adjusting, based on the corrected channel word, a channel frequency of the SDM to align with the output frequency of the output clock signal, and
the digital control signal remains constant while the PLL circuitry locks.

10. The PLL circuitry of claim 1, further comprising:
a first signal combiner, wherein a first input of the first signal combiner is communicatively coupled to the output of the TDC, a second input of the first signal combiner is communicatively coupled to a second output of the SDM, and an output of the first signal combiner is communicatively coupled to an input of the loop filter; and
a second signal combiner, wherein a first input of the second signal combiner is communicatively coupled to an output of the loop filter, a second input of the second signal combiner is configured to receive a channel word, and an output of the second signal combiner is communicatively coupled to the input of the SDM.

11. A method of operating phase-locked loop (PLL) circuitry, comprising:
generating, using a digitally controlled oscillator (DCO), an output clock signal;
generating, using a frequency divider, a feedback clock signal based on the output clock signal and a division ratio; and
locking the PLL circuitry by adjusting, using a sigma delta modulator (SDM), the division ratio according to a channel word that has been corrected based on a phase error of the feedback clock signal, wherein the DCO generates the output clock signal based on a digital control signal that remains at a constant value while the PLL circuitry locks.

12. The method of claim 11, further comprising:
generating, using a loop filter, a filtered signal based on the phase error of the feedback clock signal; and
correcting, using a signal combiner, the channel word by combining the channel word with the filtered signal.

13. The method of claim 12, further comprising:
generating, using a time-to-digital converter (TDC), a phase difference value based on the feedback clock signal and a reference clock signal; and
generating, using an additional signal combiner, the phase error based on the phase difference signal and a noise cancellation signal output by the SDM.

14. The method of claim 12, wherein locking the PLL circuitry comprises adjusting, via one or more adjustments to the corrected channel word, a channel frequency of the SDM until the channel frequency of the SDM settles on a frequency of the output clock signal.

15. Circuitry comprising:
a digitally controlled oscillator (DCO) configured to generate an output clock signal;
a frequency divider configured to generate a feedback clock signal based on the output clock signal and a division ratio;
a sigma delta modulator (SDM) communicatively coupled to an input of the frequency divider; and
a loop filter communicatively coupled between an output of the frequency divider and an input of the SDM, wherein
the loop filter is configured to generate a filtered phase error signal based on the feedback clock signal and a reference clock signal, and
the SDM is configured to adjust the division ratio of the frequency divider based on the filtered phase error signal.

16. The circuitry of claim 15, further comprising:
a time-to-digital converter (TDC) communicatively coupled between the output of the frequency divider and an input of the loop filter, wherein
the TDC is configured to generate a phase difference signal based on the feedback clock signal and the reference clock signal, and
the loop filter is configured to generate the filtered phase error signal based on the phase difference signal.

17. The circuitry of claim 16, further comprising:
a first signal combiner communicatively coupled between an output of the TDC and the input of the loop filter, wherein
the first signal combiner is configured to generate an unfiltered phase error signal based on the phase difference signal, and
the loop filter is configured to generate the filtered phase error signal by filtering the unfiltered phase error signal.

18. The circuitry of claim 17, further comprising:
a second signal combiner communicatively coupled between an output of the loop filter and the input of the SDM, wherein
the second signal combiner is configured to generate a corrected channel word by combining the filtered phase error signal with an uncorrected channel word, and
the SDM is configured to adjust the division ratio of the frequency divider based on the corrected channel word.

19. The circuitry of claim 18, wherein:
the SDM is further configured to generate a noise cancellation signal based on the corrected channel word, and
the first signal combiner is configured to generate the unfiltered phase error signal by combining the noise cancellation signal with the phase difference signal.

20. The circuitry of claim 18, wherein:
the circuitry is configured to lock a phase-locked loop that includes the frequency divider, the TDC, the first signal combiner, the loop filter, the second signal combiner, and the SDM by adjusting a channel frequency of the SDM based on the corrected channel word as the filtered phase error signal varies over time, and
the DCO remains in a constant configuration while the circuitry locks the phase-locked loop.
